(19) United States
(12) Patent Application Publication
(10) Pub. No.: US 2025/0336793 A1
(43) Pub. Date: Oct. 30, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventor: Chun-Chu LAI, Taichung City (TW)

(73) Assignee: SILICONWARE PRECISION INDUSTRIES CO., LTD., Taichung City (TW)

(21) Appl. No.: 18/774,110

(22) Filed: Jul. 16, 2024

(30) Foreign Application Priority Data
Apr. 24, 2024 (TW) 113115301

(51) Int. Cl. H01L 23/498; H01L 21/48; H01L 23/00; H01L 25/065; H05K 1/18; H05K 3/46

(52) U.S. Cl. CPC H01L 23/49838; H01L 21/4857; H01L 21/486; H05K 1/183; H05K 3/46; H01L 23/49866; H01L 23/562; H01L 24/13; H01L 24/16; H01L 24/32; H01L 24/73; H01L 25/0652; H01L 25/0657; H01L 2224/13147; H01L 2224/16227; H01L 2224/32225; H01L 2224/73204; H01L 2225/06517; H01L 2225/06548; H01L 2225/06562; H01L 2924/191

(57) ABSTRACT

An electronic package and a manufacturing method thereof are provided, wherein a circuit structure is formed on a carrier structure having a groove and through holes, a plurality of conductive pillars are disposed in a plurality of through holes to be electrically connected to the circuit structure, and electronic elements are placed in the groove to be electrically connected to the circuit structure, then a wiring structure is disposed on the carrier structure to be electrically connected to the plurality of conductive pillars, and wherein the carrier structure is a plate made of semiconductor material, thereby the manufacturing process can be simplified and the warpage problems can be reduced.

### BACKGROUND

### 1. Technical Field

The present disclosure relates to a semiconductor device, and more particularly, to an electronic package a manufacturing method thereof.

### 2. Description of Related Art

With the vigorous development of portable electronic products in recent years, various related products are gradually moving towards high density, high performance, light, thin, short and small. Therefore, various types of package on package (PoP) processes are being innovated in order to meet the requirements of thin, small size and high density.

FIG. 1 is a schematic cross-sectional view of a conventional semiconductor package 1, wherein a plurality of conductive pillars 13 are mainly formed on a circuit structure 10, at least one semiconductor chip 11 is disposed on the circuit structure 10 with a non-active surface 11b via a die-mounting adhesive layer 18, thereby a plurality of conductive bumps 12 are provided on an active surface 11a of the semiconductor chip 11, and the semiconductor chip 11 and the conductive pillars 13 are covered with an encapsulant 15. Next, a wiring structure 16 is formed on the encapsulant 15, thereby the wiring structure 16 is electrically connected to the conductive pillars 13 and the conductive bumps 12, such that a plurality of conductive elements 17 with C4 specification and other passive elements 14 can be formed on the wiring structure 16. In addition, a plurality of solder balls 19 are formed on the circuit structure 10, thereby the solder balls 19 are electrically connected to the circuit structure 10.

However, in the conventional semiconductor package 1, the coefficient of thermal expansion (CTE) of the encapsulant 15 and the CTE of the semiconductor chip 11 mismatch. Therefore, uneven thermal stress is likely to occur, which may easily cause the encapsulant 15 to warp during thermal cycles, thereby causing the semiconductor package 1 (especially the semiconductor chip 11) to crack. Moreover, the die-mounting adhesive layer 18 is prone to occur peeling problems, and may even cause the encapsulant 15 to generate voids during the manufacturing process.

Furthermore, in the conventional manufacturing method of the semiconductor package 1, the semiconductor chip 11 is disposed in a previous process, so the semiconductor chip 11 needs to undergo high-temperature thermal processes such as the production of the encapsulant 15, the wiring structure 16 (such as RDL specification) and the conductive elements 17 with C4 specification. Accordingly, the semiconductor chip 11 will be subject to thermal damage, such as thermal energy accumulation (thermal budget), and the damage will gradually increase cumulatively, thereby it is easy to exceed the load of the semiconductor chip 11, and cause the semiconductor chip 11 to be abnormal or even damaged, thereby causing product reliability problems.

In addition, directly manufacturing the conductive pillars 13 on the circuit structure 10 requires complicated processes such as exposure, development and electroplating. Therefore, it is not conducive to reducing the manufacturing cost of the semiconductor package 1.

Therefore, how to overcome the above-mentioned drawbacks of the prior art has become an urgent issue to be solved.

### SUMMARY

In view of the various deficiencies of the prior art, the present disclosure provides an electronic package, which comprises: a carrier structure having a first surface and a second surface opposite to the first surface, and having at least one groove and a plurality of through holes connecting the first surface and the second surface, wherein a plurality of recessed portions are formed on a bottom surface of the groove, thereby the groove communicates with the first surface and the second surface via the recessed portions; a circuit structure is disposed on the first surface of the carrier structure and exposed from the recessed portions and the through holes; a plurality of conductive pillars are disposed in the plurality of through holes and electrically connected to the circuit structure; an electronic element is disposed in the groove and electrically connected to the circuit structure; and a wiring structure is disposed on the second surface of the carrier structure and electrically connected to the plurality of conductive pillars.

The present disclosure also provides a method for manufacturing an electronic package, which comprises: providing a carrier structure having a first surface and a second surface opposite to the first surface, wherein at least one groove is formed on the second surface of the carrier structure; forming a circuit structure on the first surface of the carrier structure; forming a plurality of through holes connecting the first surface and the second surface on the second surface of the carrier structure, wherein a plurality of recessed portions are formed on a bottom surface of the groove; forming a plurality of conductive pillars electrically connected to the circuit structure in the through holes, wherein at least one electronic element is disposed in the groove and electrically connected to the circuit structure; and forming a wiring structure on the second surface of the carrier structure, wherein the wiring structure is electrically connected to the plurality of conductive pillars.

In the aforementioned electronic package and the manufacturing method thereof, the carrier structure is a plate made of semiconductor material.

In the aforementioned electronic package and the manufacturing method thereof, the electronic element is a semiconductor chip. For example, the electronic element has an active surface and a non-active surface opposite to the active surface, and wherein the active surface is electrically connected to the circuit structure, thereby there is no adhesive material between the electronic element and the wiring structure. Further, the electronic element is in contact with the wiring structure.

In the aforementioned electronic package and the manufacturing method thereof, a plurality of the electronic elements are disposed in the groove. For example, the plurality of electronic elements in the groove are vertically stacked with each other and electrically connected to the wiring structure. Alternatively, a plurality of the electronic elements in the groove are staggered and stacked with each other. Further, a plurality of the electronic elements are stacked on one of the electronic elements in the groove.

In the aforementioned electronic package and the manufacturing method thereof, a conductive element is formed on the circuit structure.

As can be seen from above, the electronic package and its manufacturing method of the present disclosure are based on the design of the carrier structure, wherein the electronic element is disposed in the groove, so that the carrier structure covers the electronic element, thereby facilitating to disperse thermal stress. Therefore, during thermal cycles, the present disclosure can not only avoid the conventional problems of peeling of the die-mounting adhesive layer and the generation of voids in the encapsulant, but also makes the carrier structure less likely to warp. Therefore, the problem of the electronic package or electronic element being cracked can be avoided.

Furthermore, the manufacturing method of the present disclosure is to first manufacture the circuit structure and conductive elements, and then dispose the electronic elements. Therefore, compared to the prior art, the present disclosure can prevent the electronic element from being damaged by heat accumulation generated by the RDL process and conductive elements during the manufacturing process, so as to facilitate to improve process and product reliability.

In addition, the manufacturing method of the present disclosure forms through holes on the carrier structure by laser to manufacture the conductive pillars. Therefore, compared to the prior art, the manufacturing method of the present disclosure effectively simplifies the manufacturing process, thereby facilitating to reduce the manufacturing cost of the electronic package.

### BRIEF DESCRIPTION OF THE DRAWINGS

FIG. 1 is a schematic cross-sectional view of a conventional semiconductor package.

FIG. 2A to FIG. 2E are cross-sectional schematic views illustrating a manufacturing method of an electronic package of the present disclosure.

FIG. 3A, FIG. 3B and FIG. 3C are cross-sectional views of other embodiments of FIG. 2E.

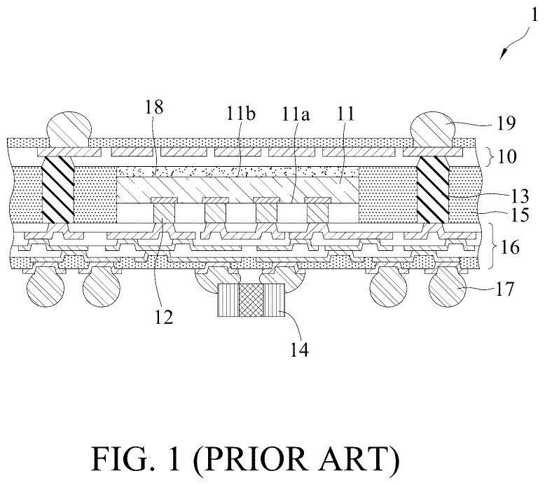

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

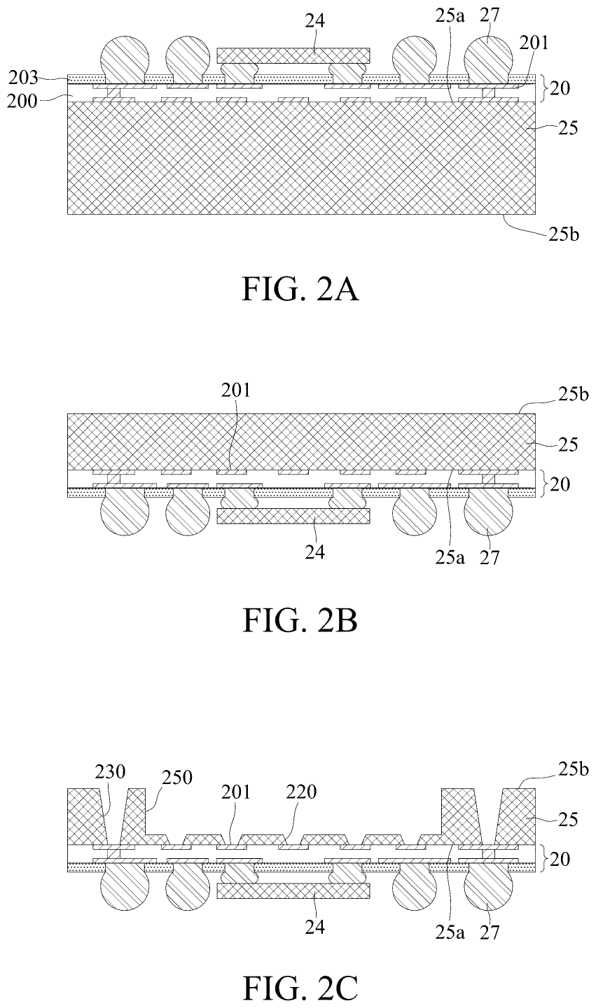

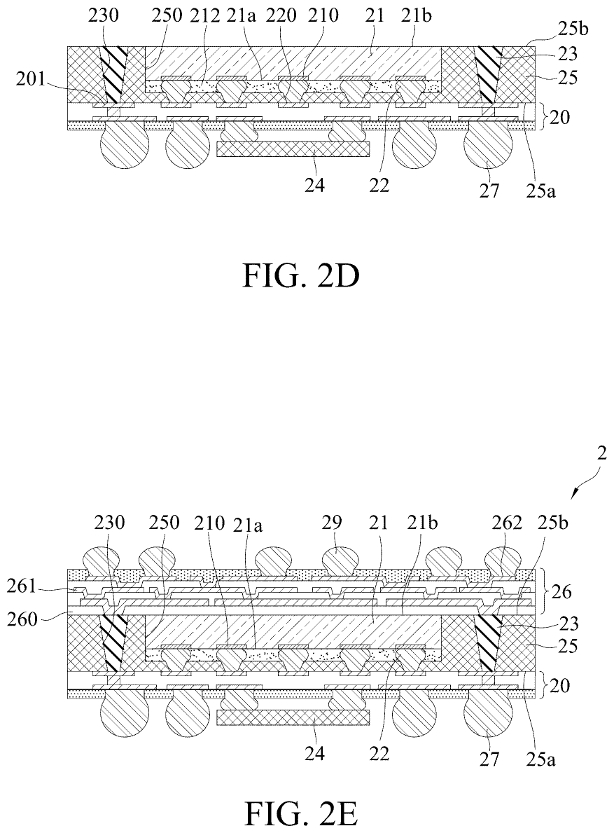

FIG. 2A to FIG. 2E are cross-sectional schematic views illustrating a manufacturing method of an electronic package 2 of the present disclosure.

As shown in FIG. 2A, a circuit structure 20 is formed on a carrier structure 25.

In one embodiment, the carrier structure 25 is, for example, a plate made of semiconductor material (such as silicon or glass), wherein the carrier structure 25 has a first surface 25a and a second surface 25b opposite to the first surface 25a, thereby the circuit structure 20 is formed on the first surface 25a of the carrier structure 25.

Furthermore, the circuit structure 20 is coreless and includes a plurality of dielectric layers 200 and a circuit layer 201, such as redistribution layer (RDL) specification, disposed on the dielectric layers 200. For example, the circuit layer 201 is made of copper, and the dielectric layer 200 is made of polybenzoxazole (PBO), polyimide (PI), prepreg (PP) or other dielectric materials.

In addition, a plurality of conductive elements 27 such as solder material, such as C4 specification, are formed on the outermost circuit layer 201 of the circuit structure 20. For example, an insulating protective layer 203 such as a solder mask can be formed on the dielectric layers 200, and a plurality of openings can be formed on the insulating protective layer 203, thereby the circuit layer 201 is exposed from the openings for connecting the plurality of conductive elements 27.

In addition, at least one auxiliary functional element 24, such as a passive element, can be connected to the outermost circuit layer 201 of the circuit structure 20.

As shown in FIG. 2B, the second surface 25b of the carrier structure 25 is thinned.

As shown in FIG. 2C, at least one groove 250 and a plurality of through holes 230 connecting the first surface 25a and the second surface 25b are formed on the second surface 25b of the carrier structure 25, and a plurality of recessed portions 220 are formed on the bottom surface of the groove 250.

In one embodiment, the groove 250 does not penetrate the carrier structure 25, and the recessed portions 220 penetrate the carrier structure 25, thereby the circuit layer 201 of the circuit structure 20 is exposed from the recessed portions 220 and the through holes 230. For example, the groove 250 can be formed by laser or other methods so that the groove 250 does not penetrate the carrier structure 25, and the recessed portions 220 and the through holes 230 can be formed by laser or other methods.

As shown in FIG. 2D, a plurality of conductive pillars 23 electrically connected to the circuit layer 201 are formed on the circuit structure 20 in the through holes 230, and at least one electronic element 21 is disposed in the groove 250 via a plurality of conductive bumps 22 placed in the recessed portions 220, thereby the electronic element 21 is in contact with the carrier structure 25.

The conductive pillars 23 are formed on the circuit layer 201 exposing from the through holes 230 by electroplating to be electrically connected to the circuit layer 201. The conductive pillars 23 are made of a metal material such as copper or solder material.

The electronic element 21 is an active element, a passive element or a combination thereof, and the like, wherein the active element is a semiconductor chip, and the passive element is a resistor, a capacitor or an inductor.

In one embodiment, the electronic element 21 is a semiconductor chip, which has an active surface 21a and a non-active surface 21b opposite to the active surface 21a, wherein electrode pads 210 of the active surface 21a of the electronic element 21 are disposed on the circuit layer 201 via a plurality of conductive bumps 22 such as copper pillars, solder balls, etc. in a face down flip-chip manner and is electrically connected to the circuit layer 201, and the conductive bumps 22 are covered with an underfill 212.

In addition, a leveling process can be performed. For example, via grinding, part of the material of the conductive pillars 23, part of the material of the electronic element 21, and part of the material of the carrier structure 25 are removed, thereby end surfaces of the conductive pillars 23, the non-active surface 21b of the electronic element 21 and the second surface 25b of the carrier structure 25 are coplanar (or flush with each other).

As shown in FIG. 2E, a wiring structure 26 is formed on the second surface 25b of the carrier structure 25, and the wiring structure 26 is electrically connected to the conductive pillars 23.

In one embodiment, the wiring structure 26 includes a plurality of insulating layers 260 and a plurality of fan-out wiring layers 261, such as RDL specifications, disposed on the insulating layers 260. Moreover, the outermost insulating layer 260 can be used as a solder mask, thereby the outermost wiring layer 261 is partially exposed from the solder mask and used as an electrical contact pad 262, and a conductive material 29 can be disposed on the electrical contact pad 262. Subsequently, the wiring structure 26 can be mounted and electrically connected to a package module (not shown) such as a double data rate (DDR) synchronous dynamic random access memory structure via the conductive material 29 (solder material). For example, the wiring layer 261 is made of copper, and the insulating layer 260 is made of polybenzoxazole (PBO), polyimide (PI), prepreg (PP), or other dielectric materials.

In subsequent processes, the electronic package 2 can be connected to an electronic device (not shown) such as a circuit board via the conductive elements 27.

Therefore, in the manufacturing method of the present disclosure, a plate of semiconductor material is mainly used as a design of the carrier structure 25, thereby the electronic element 21 is placed in the groove 250, thereby the carrier structure 25 covers the electronic element 21. Accordingly, the coefficient of thermal expansion (CTE) of the carrier structure 25 matches the CTE of the electronic element 21, thereby facilitating to disperse thermal stress. Therefore, compared to the prior art, the manufacturing method of the present disclosure can not only avoid problems such as the peeling of the conventional die-mounting adhesive layer and the generation of voids in the encapsulant during thermal cycle, but also make the carrier structure 25 less likely to warp. Accordingly, reliability problems such as the electronic package 2 or the electronic element 21 being cracked, the conductive elements 27 being dropped and electrically disconnected, the conductive elements 27 not being soldered (non-wetting), or peeling of the circuit structure 20 (or wiring structure 26) can be avoided. This can further improve the reliability of terminal electronic products (such as computers, mobile phones, etc.) using the electronic package.

Furthermore, the manufacturing method of the present disclosure is to first manufacture the circuit structure 20 and the conductive elements 27 with C4 specifications, and then dispose the electronic element 21. Therefore, compared to the prior art (which first disposes the semiconductor chip, and then manufactures the wiring structure and conductive elements with C4 specification), the present disclosure can prevent the electronic element 21 (or semiconductor chip) from being damaged by heat accumulation generated by the RDL process and the conductive elements 27 during the manufacturing process, thereby improving process and product reliability.

In addition, the manufacturing method of the present disclosure forms the through holes 230 on the carrier structure 25 by laser to make the conductive pillars 23. Therefore, compared with the conventional complicated processes such as exposure, development and electroplating, the manufacturing method of the present disclosure effectively simplifies the manufacturing process, thereby facilitating to reduce the manufacturing cost of the electronic package 2.

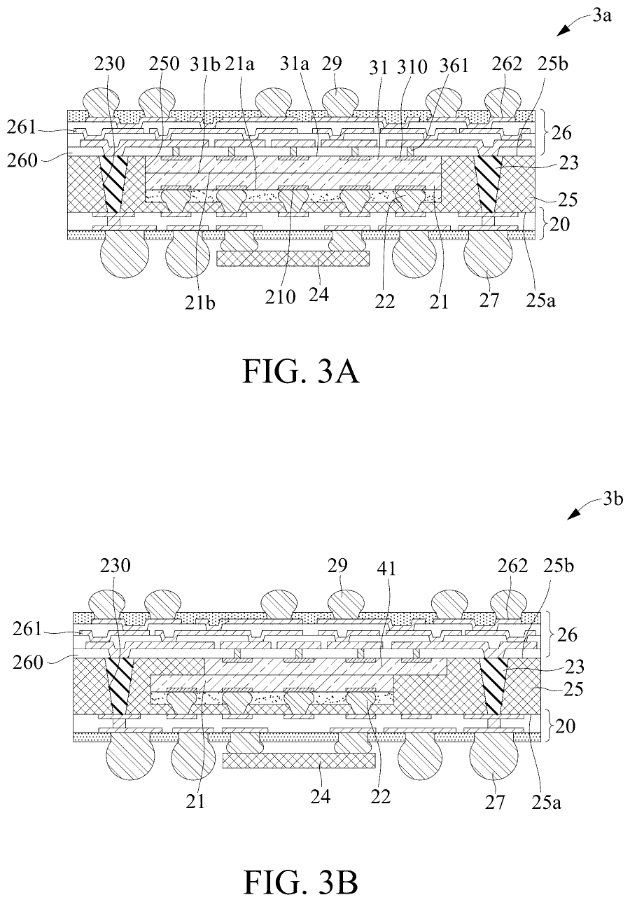

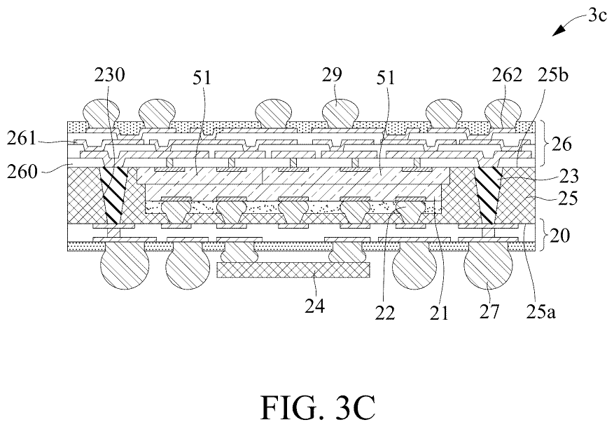

In addition, in other embodiments, such as an electronic package 3a shown in FIG. 3A, a plurality of electronic elements 21, 31 can be placed in the groove 250, thereby the plurality of electronic elements 21, 31 are vertically stacked with each other in the groove 250, wherein the upper and lower electronic elements 21 and 31 are active elements, passive elements or a combination of the two. For example, the electronic elements 21, 31 are semiconductor chips, which have active surfaces 21a, 31a and non-active surfaces 21b, 31b opposite to the active surfaces 21a, 31a, wherein electrode pads 210 of the active surface 21a of the lower electronic element 21 are disposed on the circuit layer 201 via a plurality of conductive bumps 22 such as copper pillars, solder balls, etc. in a face down flip-chip manner and is electrically connected to the circuit layer 201, and the conductive bumps 22 are covered with an underfill 212, while the non-active surface 31b of the upper electronic element 31 is adhered to the non-active surface 21b of the lower electronic element 21 via a bonding layer such as glue. Therefore, electrode pads 310 of the active surface 31a of the upper electronic element 31 are electrically connected to the wiring layer 361 of the wiring structure 26.

In other embodiments, such as an electronic package 3b shown in FIG. 3B, a plurality of electronic elements 21, 41 can be placed in the groove 250, and the lower electronic element 21 and the upper electronic element 41 are staggered and stacked with each other; or, such as an electronic package 3c shown in FIG. 3C, a plurality of electronic elements 21, 51 can be placed in the groove 250, wherein the plurality of electronic elements 51 can be stacked on the lower electronic component 21 in an offset manner.

The present disclosure provides an electronic package 2, 3a, 3b, 3c, which includes: a carrier structure 25, at least one (or a plurality of) electronic elements 21, 31, 41, 51, a plurality of conductive pillars 23, a circuit structure 20 and a wiring structure 26.

The carrier structure 25 has a first surface 25a and a second surface 25b opposite to the first surface 25a, wherein the carrier structure 25 has at least one groove 250 and a plurality of through holes 230 connecting the first surface 25a and the second surface 25b, and a plurality of recessed portions 220 are formed on the bottom surface of the groove 250, thereby the groove 250 communicates with the first surface 25a and the second surface 25b via the recessed portions 220.

The circuit structure 20 is disposed on the first surface 25a of the carrier structure 25 and is exposed from the recessed portions 220 and the through holes 230.

The conductive pillars 23 are disposed in the plurality of through holes 230 and are electrically connected to the circuit structure 20.

The electronic elements 21, 31, 41, 51 are disposed in the groove 250 and are electrically connected to the circuit structure 20 and contact to the carrier structure 25.

The wiring structure 26 is disposed on the second surface 25b of the carrier structure 25 and is electrically connected to the conductive pillars 23.

In one embodiment, the carrier structure 25 is a plate made of semiconductor material.

In one embodiment, the electronic elements 21, 31, 41, 51 are semiconductor chips. For example, the electronic elements 21 and 31 have active surfaces 21a and 31a and non-active surfaces 21b and 31b opposite to the active surfaces 21a and 31a, wherein the active surface 21a is electrically connected to the circuit structure 20, and there is no adhesive material between the electronic elements 21, 31, 41, 51 and the wiring structure 26. Further, the electronic elements 21, 31, 41, 51 are in contact with the wiring structure 26.

In one embodiment, a plurality of the electronic elements 21, 31, 41, 51 are disposed in the groove 250. For example, the plurality of electronic elements 21 and 31 in the groove 250 are vertically stacked with each other and electrically connected to the wiring structure 26. Alternatively, the plurality of electronic elements 21 and 41 in the groove 250 are staggered and stacked with each other. Furthermore, in the groove 250, a plurality of electronic elements 51 can be stacked on the electronic element 21 in an offset manner.

In one embodiment, conductive elements 27 are formed on the circuit structure 20.

In summary, the electronic package and its manufacturing method of the present disclosure are based on the design of the carrier structure, wherein the electronic element is disposed in the groove, so that the carrier structure covers the electronic element, thereby facilitating to disperse thermal stress. Therefore, during thermal cycles, the present disclosure can not only avoid the conventional problems of peeling of the die-mounting adhesive layer and the generation of voids in the encapsulant, but also makes the carrier structure less likely to warp. Therefore, the problem of the electronic package or electronic element being cracked can be avoided.

Furthermore, the manufacturing method of the present disclosure is to first manufacture the circuit structure and conductive elements, and then dispose the electronic elements. Therefore, the present disclosure can prevent the electronic element (or semiconductor chip) from being damaged by heat accumulation generated by the RDL process and conductive elements during the manufacturing process, so as to facilitate to improve process and product reliability.

In addition, the manufacturing method of the present disclosure uses laser to form through holes on the carrier structure to manufacture the conductive pillars. Therefore, the manufacturing method of the present disclosure effectively simplifies the manufacturing process, thereby facilitating to reduce the manufacturing cost of the electronic package 2.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a first surface and a second surface opposite to the first surface, and having at least one groove and a plurality of through holes connecting the first surface and the second surface, wherein a plurality of recessed portions are formed on a bottom surface of the groove, thereby the groove communicates with the first surface and the second surface via the recessed portions;
a circuit structure disposed on the first surface of the carrier structure and exposed from the recessed portions and the through holes;
a plurality of conductive pillars disposed in the plurality of through holes and electrically connected to the circuit structure;
an electronic element disposed in the groove and electrically connected to the circuit structure; and
a wiring structure disposed on the second surface of the carrier structure and electrically connected to the plurality of conductive pillars.

2. The electronic package of claim 1, wherein the carrier structure is a plate made of semiconductor material.

3. The electronic package of claim 1, wherein the electronic element is a semiconductor chip.

4. The electronic package of claim 3, wherein the electronic element has an active surface and a non-active surface opposite to the active surface, and wherein the active surface is electrically connected to the circuit structure, thereby there is no adhesive material between the electronic element and the wiring structure.

5. The electronic package of claim 4, wherein the electronic element is in contact with the wiring structure.

6. The electronic package of claim 1, wherein a plurality of the electronic elements are disposed in the groove.

7. The electronic package of claim 6, wherein the plurality of electronic elements in the groove are vertically stacked with each other and electrically connected to the wiring structure.

8. The electronic package of claim 6, wherein a plurality of the electronic elements in the groove are staggered and stacked with each other.

9. The electronic package of claim 6, wherein a plurality of the electronic elements are stacked on one of the electronic elements in the groove.

10. The electronic package of claim 1, wherein a conductive element is formed on the circuit structure.

11. A method for manufacturing an electronic package, comprising:
providing a carrier structure having a first surface and a second surface opposite to the first surface, wherein at least one groove is formed on the second surface;
forming a circuit structure on the first surface of the carrier structure;
forming a plurality of through holes connecting the first surface and the second surface of the carrier structure, wherein a plurality of recessed portions are formed on a bottom surface of the groove;
forming a plurality of conductive pillars electrically connected to the circuit structure in the through holes, wherein at least one electronic element is disposed in the groove and electrically connected to the circuit structure; and
forming a wiring structure on the second surface of the carrier structure, wherein the wiring structure is electrically connected to the plurality of conductive pillars.

12. The method of claim 11, wherein the carrier structure is a plate made of semiconductor material.

13. The method of claim 11, wherein the electronic element is a semiconductor chip.

14. The method of claim 13, wherein the electronic element has an active surface and a non-active surface opposite to the active surface, and wherein the active surface is electrically connected to the circuit structure, thereby there is no adhesive material between the electronic element and the wiring structure.

15. The method of claim 14, wherein the electronic element is in contact with the wiring structure.

16. The method of claim 11, wherein a plurality of the electronic elements are disposed in the groove.

17. The method of claim 16, wherein a plurality of the electronic elements in the groove are vertically stacked with each other and electrically connected to the wiring structure.

18. The method of claim 16, wherein a plurality of the electronic elements in the groove are staggered and stacked with each other.

19. The method of claim 16, wherein a plurality of the electronic elements are stacked on one of the electronic elements in the groove.

20. The method of claim 11, wherein a conductive element is formed on the circuit structure.
